(19) United States
(12) Patent Application Publication
(10) Pub. No.: US 2010/0141087 A1
(43) Pub. Date: Jun. 10, 2010

(54) SURFACE ACOUSTIC WAVE BASED SENSOR APPARATUS AND METHOD UTILIZING SEMI-SYNCHRONOUS SAW RESONATORS

(75) Inventors: Cazimir Bostan, Bucharest (RO); Stefan Dan Costea, Bucharest (RO); Viorel Avramescu, Bucharest (RO); Cornel Cobianu, Bucharest (RO)

Correspondence Address: HONEYWELL INTERNATIONAL INC.;PATENT SERVICES, 101 COLUMBIA ROAD, P O BOX 2245, MORRISTOWN, NJ, 07962-2245, US

(73) Assignee: Honeywell International Inc.

(21) Appl. No.: 12/332,064

(22) Filed: Dec. 10, 2008

(51) Int. Cl. H01L 41/047

(52) U.S. Cl. 310/313 D

(57) ABSTRACT

A SAW based sensor apparatus utilizing semi-synchronous SAW resonator having a single resonance at Bragg frequency with very high quality factor is disclosed. The semi-synchronous SAW resonator includes at least one inter-digital transducer, which generates and receives surface acoustic wave and a number of grating reflectors, which reflect the surface acoustic wave and generate a standing wave between the reflectors, The interdigital transducer and the grating reflectors can be fabricated on a substrate (e.g., quartz) by photolithographic process. The resonance condition is independent of transducer directivity and reflection coefficient per finger. Such a SAW based sensor apparatus having three semi-synchronous SAW resonators can be utilized for measuring pressure and temperature for a wireless tire-pressure monitoring system.

### TECHNICAL FIELD

Embodiments are generally related to SAW (Surface Acoustic Wave) sensing devices and applications. Embodiments are also related to semi-synchronous SAW resonators. Embodiments are further related to SAW-based sensor apparatus utilizing semi-synchronous SAW resonators.

### BACKGROUND OF THE INVENTION

Surface Acoustic Wave (SAW) devices are electronic components that generate guided acoustic waves along a surface of the device. The SAW devices can be employed as resonators, filters, oscillators and transformers based on the transduction of the acoustic waves. Such devices are generally fabricated on single crystal anisotropic substrates that are piezoelectric (e.g., quartz, lithium niobate, lithium tantalate, lanthanum gallium silicate, etc). SAW devices typically include one or more pairs of interdigital transducers to convert the electrical signals applied to the device into electromechanical surface acoustic waves generated in the device. The surface acoustic wave is an acoustic wave produced on the surface of a material having some elasticity, with an amplitude that typically decays exponentially with the depth of the substrate.

SAW resonators have important practical applications as wireless sensors (e.g. pressure, temperature). The desired features of the SAW resonator includes single resonance with precisely controlled frequency, high quality factor, in/out impedance matching and small size. However, it is difficult to achieve all these features simultaneously. For example, a synchronous SAW resonator has typically two resonances at both edges of the stop band and their frequencies depend on reflection coefficient per finger, which in turn depends on surface loading. On the other hand, transducer directivity has to be taken into account in the resonance condition. Directivity is a figure of merit, which measures the power density in the direction of its strongest emission of the acoustic waves generated by the transducer. Therefore, there is a certain degree of uncertainty in prescribing the resonance frequency, its main source being the deposition tolerance of metal such as its thickness. In one prior art SAW sensor, the directivity of the sensor is compensated by shifting the gratings with respect to the transducer, which results in inaccuracies due to determined directivity.

Based on the foregoing, it is believed that a need exists for an improved SAW based sensor apparatus utilizing a semi-synchronous SAW resonator having single resonance with high quality factor, in/out impedance matching and small size simultaneously.

### BRIEF SUMMARY

The following summary is provided to facilitate an understanding of some of the innovative features unique to the embodiments disclosed and is not intended to be a full description. A full appreciation of the various aspects of the embodiments can be gained by taking the entire specification, claims, drawings, and abstract as a whole.

It is, therefore, one aspect of the present invention to provide for an improved sensing device and applications thereof.

It is another aspect of the present invention to provide for an improved SAW based sensor apparatus.

It is a further aspect of the present invention to provide for improved SAW sensor apparatus utilizing semi-synchronous SAW resonators.

The aforementioned aspects and other objectives and advantages can now be achieved as described herein. A SAW based sensor apparatus utilizing semi-synchronous SAW resonators having a single resonance at Bragg frequency with very high quality factor is disclosed. The semi-synchronous SAW resonators includes at least one inter-digital transducer, which generates and receives surface acoustic wave and a number of grating reflectors, which reflect the surface acoustic wave and generate a standing wave between the reflectors. The inter-digital transducer and the grating reflectors can be fabricated on a substrate (e.g., quartz) by photolithographic process. The resonance condition is independent of transducer directivity and reflection coefficient per finger. Such a SAW based sensor apparatus having three semi-synchronous SAW resonators can be utilized for measuring pressure (PSAW) and temperature (TSAW) and the third one being utilized as a reference (RSAW) for a wireless tire-pressure monitoring system (TPMS).

The design of the SAW resonators is based on a combination of finite-element (FEM) numerical calculations and coupling-of-modes (COM) analytical calculations. The distance between the interdigital transducer and a left grating reflector is λ/2 and the distance between the interdigital transducer and a right grating reflector is 3λ/4. The interdigital transducer can produce a single resonance, which can be independent of the directivity and reflection coefficient. The interdigital transducer and the grating reflectors have the same frequency and the left grating is made synchronous with the interdigital transducer. The quality factor and target values of electrical admittance can be achievable with the small-sized SAW resonators.

### BRIEF DESCRIPTION OF THE DRAWINGS

The accompanying figures, in which like reference numerals refer to identical or functionally-similar elements throughout the separate views and which are incorporated in and form a part of the specification, further illustrate the embodiments and, together with the detailed description, serve to explain the embodiments disclosed herein.

FIG. 1 illustrates a perspective view of a semi-synchronous SAW resonator, in accordance with a preferred embodiment;

FIG. 2 illustrates a schematic view of a SAW based sensor apparatus utilizing semi-synchronous SAW resonator, which can be implemented in accordance with a preferred embodiment;

FIGS. 3-4 depicts a graphical representation illustrating electrical characteristics of a one port semi-synchronous SAW resonator, in accordance with a preferred embodiment;

FIG. 5 illustrates a tire pressure monitoring system utilizing semi-synchronous SAW resonators for sensing temperature and pressure, which can be implemented in accordance with an exemplary embodiment; and

FIG. 6 illustrates a table depicting semi-synchronous SAW resonator parameters for a tire pressure monitoring system, in accordance with an alternative embodiment.

### DETAILED DESCRIPTION

The particular values and configurations discussed in these non-limiting examples can be varied and are cited merely to illustrate at least one embodiment and are not intended to limit the scope thereof.

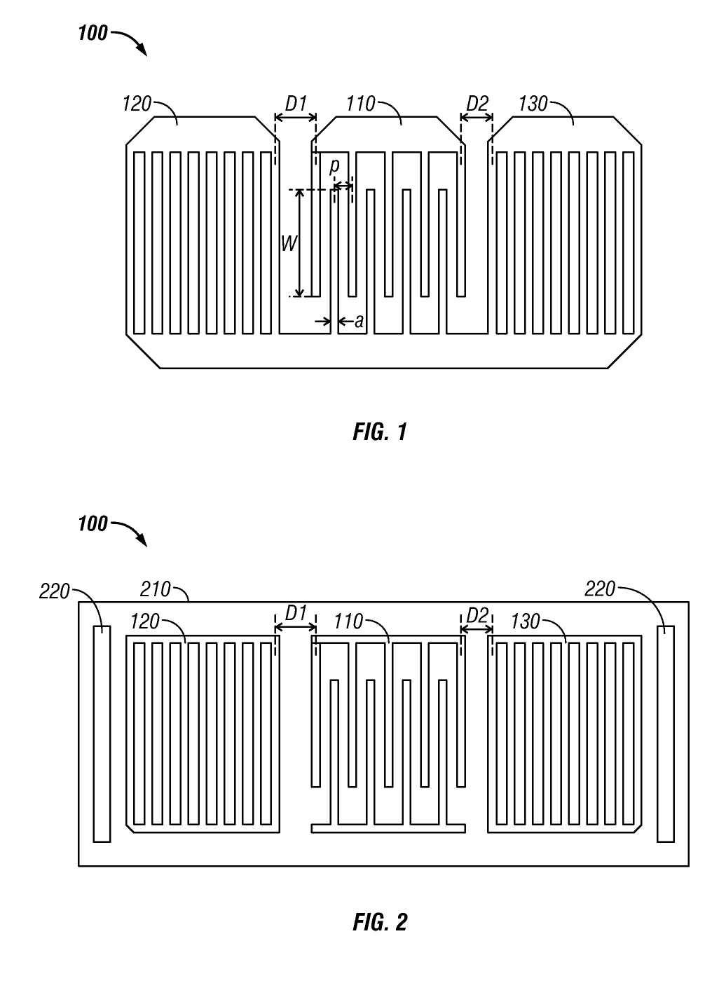

FIG. 1 illustrates a perspective view of a semi-synchronous SAW resonator 100, in accordance with a preferred embodiment. The semi-synchronous SAW resonator 100 generally includes an interdigital transducer 110 placed between a pair of grating reflectors 120 and 130. The interdigital transducer 110 facilitates the semi-synchronous SAW resonator 100 in conversion of electrical signals into surface acoustic waves and vice versa. The interdigital transducers 110 can be composed of a series of thin metal strips vapor-deposited onto a substrate 210, as shown in FIG. 2, these being referred to as finger electrodes, and being inter digitally or alternately connected to a plurality of bus bars (not shown) placed above the interdigital transducer 110. When an alternating electrical voltage is applied to the bus bar, a surface deformation of the substrate 210 arises due to the piezoelectric effect, such deformation propagating as a mechanical wave in two opposite directions at right angles to the longest expanse of the finger electrodes.

The interdigital transducer 110 can be made synchronous with the grating reflector 120. D1 and D2 are the distances between the interdigital transducer 110 and the left grating 120 and the right grating 130, respectively. The interdigital transducer 110 and the grating reflectors 120 and 130 have the same frequency and the left grating 120 is made synchronous with the interdigital transducer 110, so that D1=λ/2. The other space D2=3λ/4. The interdigital transducer 110 and reflector gratings 120 and 130 all have the same Bragg frequency to produce a single resonance with high quality factor. The Bragg frequency is the frequency at which the individual reflections from each of the periodically spaced distances add up in phase to maximize the reflection. Such a Bragg frequency occurs at a frequency where the spacing can be 114 of a wavelength on the transmission line. The interdigital transducer 110 can produce a single resonance, which can be independent of the directivity and reflection coefficient. The directivity is the power density of the signal in the direction of the strongest discharge emitted by the transducer 110, whereas the reflection coefficient describes either the amplitude or the intensity of a reflected wave relative to an incident wave.

FIG. 2 illustrates a schematic view of a SAW based sensor apparatus 200 utilizing semi-synchronous SAW resonator 100, which can be implemented in accordance with a preferred embodiment. Note that in FIGS. 1-4, identical or similar parts are generally indicated by identical reference numerals. The semi-synchronous SAW resonator 100 can be fabricated on the substrate 210, for example, a quartz crystal substrate to form a piezoelectric effect by utilizing a photolithographic process. The semi-synchronous SAW resonator 100 can be a one-port SAW resonator, which consists of the interdigital transducer 110 for both voltage input and output, and two reflected gratings 120 and 130 on both sides. Note that the embodiments discussed herein should not be construed in any limited sense. It can be appreciated that such embodiments reveal details of the structure of a preferred form necessary for a better understanding of the invention and may be subject to change by skilled persons within the scope of the invention without departing from the concept thereof.

The SAW based sensor apparatus 200 further includes acoustic absorbers 220 that can be fabricated on the quartz crystal substrate 210 for absorbing the surface acoustic waves to prevent distortion of the signal. Such SAW based sensor apparatus 200 eliminates possible inaccuracies introduced by the determined directivity. As an external voltage input to the resonator 100, the interdigital transducer 110 converts electrical signals into surface acoustic waves, which then propagate away from the interdigital transducer 110. As the waves hit the metal gratings 120 and 130, they are reflected back to the interdigital transducer 110 and form a resonant cavity.

The frequency response of the SAW resonator 100 can be calculated based on a combination of finite-element (FEM) numerical calculations and coupling-of-modes (COM) analytical calculations. The COM parameters can be, for example: surface wave velocity, reflection parameter, propagation loss, transduction parameter, thin film finger capacitance, finger resistance and other appropriate parameters. The FEM is a technique originally developed for numerical solution of complex problems in structural mechanics. The coupling-of-mode analysis can be utilized in order to analyze the structure, specifically for the film thickness of the interdigital transducer 110, and the FEM can be employed for evaluating the coefficients of COM equations.

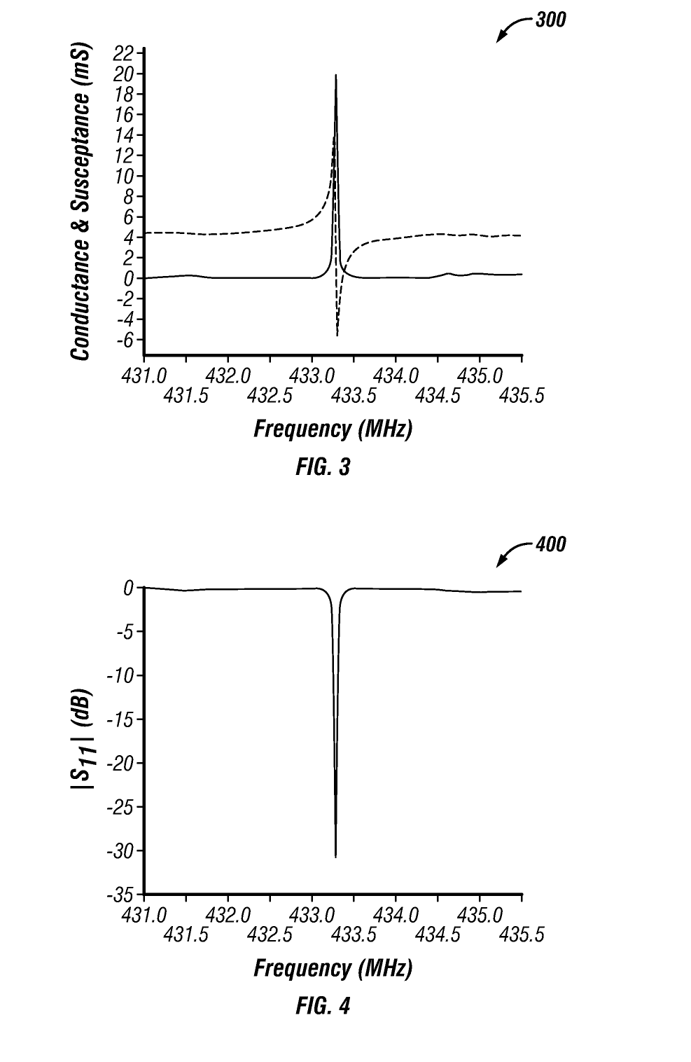

FIGS. 3-4 depict a graphical representation 300 and 400 illustrating electrical characteristics of the one port semi-synchronous SAW resonator 100, in accordance with a preferred embodiment. The graphical representation 300 illustrates the conductance and susceptance of the semi-synchronous SAW resonator 100. FIG. 4 illustrates insertion loss of the semi-synchronous SAW resonator 100. The insertion loss is the decrease in transmitted signal power resulting from the insertion of a device in a transmission line, which can be usually expressed relative to the signal power delivered to the same part before insertion. Insertion loss is usually expressed in decibels (dB). The graph 300 represents electrical characteristics of a one-port semi-synchronous resonator on STx+18 quartz with electrodes of thickness h=120 nm. It can be appreciated that the graphs 300-400 illustrated and described herein are not considered limiting features of the present invention, but merely represent varying embodiments of the present invention, and examples of test data, which may vary in accordance with other embodiments.

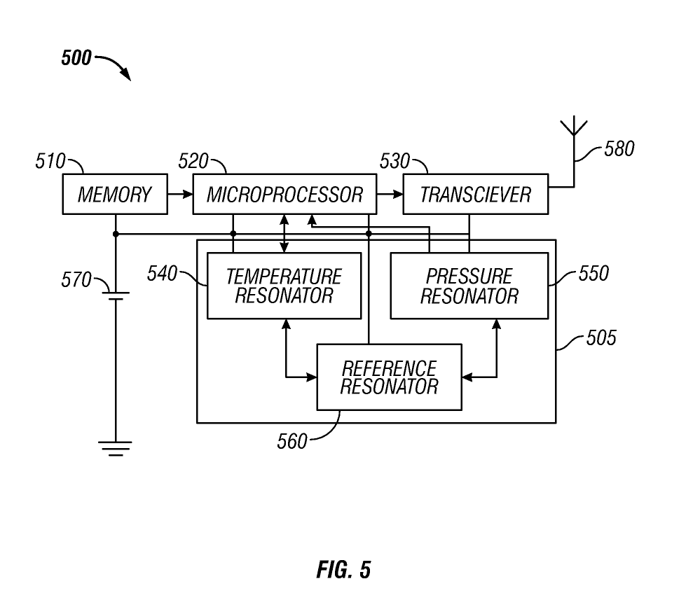

FIG. 5 illustrates a tire pressure monitoring system (TPMS) 500 utilizing semi-synchronous SAW resonators 100 for sensing temperature and pressure, which can be implemented in accordance with a preferred embodiment. The TPMS 500 generally includes three SAW resonators of semi-synchronous type; placed on quartz ST cut 505. The three SAW resonators comprise a temperature SAW resonator (TSAW) 540, a pressure SAW resonator (PSAW) 550, and a reference SAW resonator (RSAW) 560. The TSAW 540 and PSAW 550 can be utilized for measuring the temperature and pressure of the air in the cavity of a tire (not shown), while the RSAW 560 can be utilized as the reference to the TSAW 540 and PSAW 550. The temperature and pressure values related to the tire can be stored in a memory 510. Further, a transceiver 530 with an antenna 580 can be provided for a bi-directional wireless communication with the vehicle in which TPMS 500 can be utilized. A microprocessor 520 can be utilized to manage the functioning of the memory 510 and of the transmitting section of the transceiver 530. Furthermore, a cell or battery 570 can be provided to supply the electrical energy required for the TPMS 500.

The input of the transducer can be connected to the radiofrequency antenna 580. When the antenna 580 receives an electromagnetic signal, this gives rise to waves over the surface of the substrate 505 which are themselves converted into electromagnetic energy on the antenna 580. Thus, the device, consisting of a resonators 540, 550 and 560 connected to the antenna 580, has a response at the resonant frequency of the resonator and it is possible to measure this frequency remotely. It is thus possible to produce remotely interrogable sensors. This possibility is an important advantage of surface acoustic waves and is used in the context of tire pressure sensors 500 since it is advantageous to be able to place the sensor in the tire, while the interrogating electronics are placed in the vehicle.

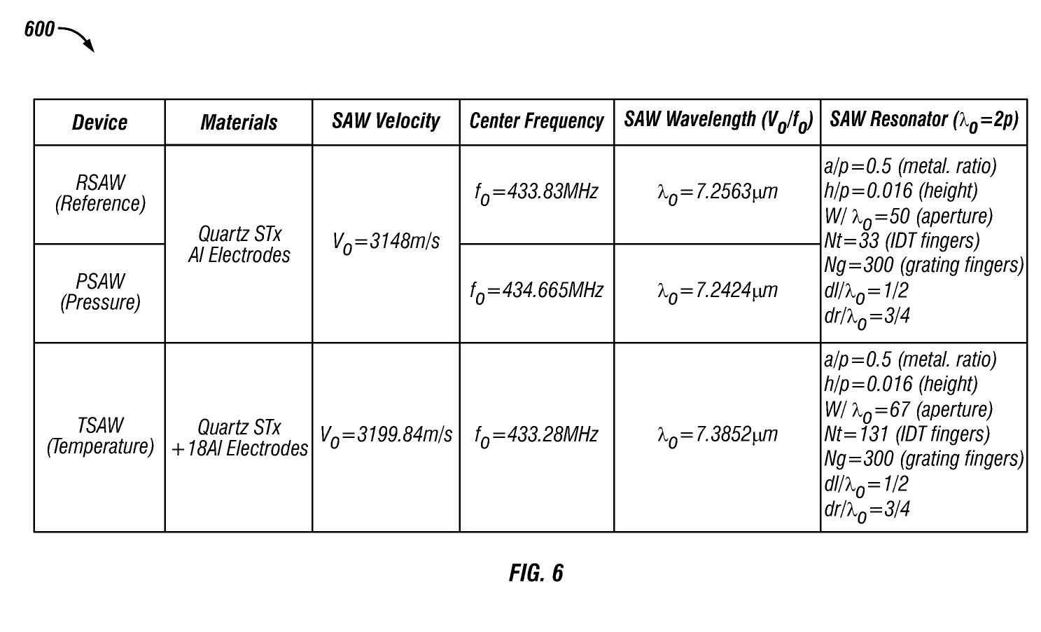

FIG. 6 illustrates a table 600 depicting the semi-synchronous SAW resonator parameters for a tire pressure monitoring system 500, in accordance with a preferred embodiment. The table 600 depicts the SAW device parameters related to TSAW 540, PSAW 550 and RSAW 560. The semi-synchronous SAW resonator 100 has a single resonance at Bragg frequency with very high quality factor. Also, the semi-synchronous SAW resonator 100 is small in size due to which the target values and quality factor are achievable.

It will be appreciated that variations of the above-disclosed and other features and functions, or alternatives thereof, may be desirably combined into many other different systems or applications. Also, that various presently unforeseen or unanticipated alternatives, modifications, variations or improvements therein may be subsequently made by those skilled in the art which are also intended to be encompassed by the following claims.

What is claimed is:

1. A SAW-based sensor apparatus, comprising:
a semi-synchronous SAW resonator comprising at least one interdigital transducer with a plurality of interdigital fingers disposed on a piezoelectric substrate for generating a surface acoustic wave in accordance with an input electric signal; and
a plurality of grating reflectors placed on both sides of said at least one interdigital transducer to reflect said surface acoustic wave and form a resonant cavity between said plurality of grating reflectors such that said semi-synchronous SAW resonator possesses a single resonance at a Bragg frequency, with a high quality factor.

2. The apparatus of claim 1 further comprising:
a plurality of acoustic absorbers for absorbing said surface acoustic wave to prevent distortion of said surface acoustic wave signal.

3. The apparatus of claim 1 wherein said resonance is independent of said at least one interdigital transducer directivity.

4. The apparatus of claim 1 wherein said semi-synchronous SAW resonator is configured based on a finite-element method (FEM) and a coupling-of-modes analysis (COM).

5. The apparatus of claim 1 wherein:
a first distance between said at least one interdigital transducer and a left grating reflector is approximately λ/2; and
a second distance between said at least one interdigital transducer and a right grating reflector is approximately 3λ/4.

6. The apparatus of claim 1 wherein said semi-synchronous SAW resonator is configured for use in a tire pressure monitoring system for sensing pressure and temperature.

7. The apparatus of claim 6 wherein said tire pressure monitoring system comprises at least three semi-synchronous SAW resonators for sensing pressure and temperature.

8. The apparatus of claim 1 further comprising:
a plurality of acoustic absorbers for absorbing said surface acoustic wave to prevent distortion of said surface acoustic wave signal;
wherein said resonance is independent of said at least one interdigital transducer directivity;
wherein said semi-synchronous SAW resonator is configured for use in a tire pressure monitoring system for sensing pressure and temperature; and
wherein said tire pressure monitoring system comprises at least three semi-synchronous SAW resonator for sensing pressure and temperature.

9. The apparatus of claim 8 wherein said semi-synchronous SAW resonator is configured based on a finite-element method (FEM) and a coupling-of-modes analysis (COM).

10. The apparatus of claim 8 wherein:
a first distance between said at least one interdigital transducer and a left grating reflector is approximately λ/2; and
a second distance between said at least one interdigital transducer and a right grating reflector is approximately 3λ/4.

11. A SAW-based sensor apparatus, comprising:
a semi-synchronous SAW resonator comprising at least one interdigital transducer with a plurality of interdigital fingers disposed on a piezoelectric substrate for generating a surface acoustic wave in accordance with an input electric signal;
a plurality of grating reflectors placed on both sides of said at least one interdigital transducer to reflect said surface acoustic wave and form a resonant cavity between said plurality of grating reflectors such that said semi-synchronous SAW resonator possesses a single resonance at a Bragg frequency, with a high quality factor; and
a plurality of acoustic absorbers for absorbing said surface acoustic wave to prevent distortion of said surface acoustic wave signal, wherein said resonance is independent of said at least one interdigital transducer directivity.

12. The apparatus of claim 11 wherein said semi-synchronous SAW resonator is configured based on a finite-element method (FEM) and a coupling-of-modes analysis (COM).

13. The apparatus of claim 11 wherein:
a first distance between said at least one interdigital transducer and a left grating reflector is approximately λ/2; and
a second distance between said at least one interdigital transducer and a right grating reflector is approximately 3λ/4.

14. The apparatus of claim 11 wherein said semi-synchronous SAW resonator is configured for use in a tire pressure monitoring system for sensing pressure and temperature.

15. The apparatus of claim 14 wherein said tire pressure monitoring system comprises at least three semi-synchronous SAW resonators for sensing pressure and temperature.

16. A method for configuring a SAW-based sensor apparatus, comprising:
configuring a semi-synchronous SAW resonator to include at least one interdigital transducer with a plurality of interdigital fingers disposed on a piezoelectric substrate for generating a surface acoustic wave in accordance with an input electric signal; and
placing a plurality of grating reflectors on both sides of said at least one interdigital transducer to reflect said surface acoustic wave and form a resonant cavity between said plurality of grating reflectors such that said semi-synchronous SAW resonator possesses a single resonance at a Bragg frequency, with a high quality factor.

17. The apparatus of claim 1 further comprising:
providing a plurality of acoustic absorbers for absorbing said surface acoustic wave to prevent distortion of said surface acoustic wave signal; and
associating said plurality of acoustic absorbers with said plurality of grating reflectors and said semi-synchronous SAW resonator.

18. The method of claim 16 further comprising configuring said resonance to be independent of said at least one interdigital transducer directivity.

19. The method of claim 16 further comprising configuring said semi-synchronous SAW resonator based on a finite-element method (FEM) and a coupling-of-modes analysis (COM).

20. The method of claim 16 further comprising:
configuring a first distance between said at least one interdigital transducer and a left grating reflector to be approximately λ/2; and
configuring a second distance between said at least one interdigital transducer and a right grating reflector to be approximately 3λ/4.
